(19) United States
(12) Patent Application Publication
(10) Pub. No.: US 2025/0267875 A1
(43) Pub. Date: Aug. 21, 2025

(54) FERROELECTRIC FIELD EFFECT TRANSISTOR WITH DOUBLE SPACER AND METHOD OF MANUFACTURING THE SAME

(71) Applicant: RESEARCH & BUSINESS FOUNDATION SUNGKYUNKWAN UNIVERSITY, Suwon-si (KR)

(72) Inventors: So Young KIM, Seoul (KR); Jeong Taek KONG, Seoul (KR); Hyung Min CHO, Suwon-si (KR); Hyun Joon JEONG, Suwon-si (KR); Jin Young CHOI, Suwon-si (KR)

(21) Appl. No.: 19/045,725

(22) Filed: Feb. 5, 2025

(30) Foreign Application Priority Data
Feb. 15, 2024 (KR) 10-2024-0021968

(51) Int. Cl. H10B 51/30; H10D 30/01; H10D 30/69

(52) U.S. Cl. CPC H10B 51/30; H10D 30/0415; H10D 30/701

(57) ABSTRACT

Provided is a ferroelectric field effect transistor. The ferroelectric field effect transistor includes: a body layer including a source region, a drain region spaced apart from the source region, and an intermediate region disposed between the source region and the drain region; a gate structure including a gate dielectric layer, a ferroelectric layer, and a gate electrode which are sequentially stacked on the intermediate region of the body layer; and a double spacer disposed on a side wall of the gate structure, in which the double spacer includes a high-k lower spacer and a low-k upper spacer disposed on the lower spacer.

### BACKGROUND OF THE INVENTION

### 1. Field of the Invention

The present invention relates to a ferroelectric field effect transistor and a method of manufacturing the same, and more specifically, to a ferroelectric field effect transistor equipped with a double spacer and a method of manufacturing the same.

### 2. Description of the Related Art

A ferroelectric field effect transistor is a memory device that adjusts a threshold voltage of the device using polarization recorded in a ferroelectric. In the initial ferroelectric field effect transistor, a perovskite material has been used as a ferroelectric layer, but the thickness of the ferroelectric layer exceeding hundreds of nm has acted as a limitation. Thereafter, as the ferroelectric property of hafnium oxide has been found, sufficient performance may be obtained even with the thickness of 1 to 10 nm. Accordingly, all the recent ferroelectric field effect transistors have been studied based on the hafnium oxide ferroelectric layer, and many studies have been conducted to maintain polarization due to repetition of a write operation and to improve power consumption and latency.

In the ferroelectric field effect transistor, a value of the threshold voltage of the device varies depending on the polarization of the ferroelectric layer. When the directions of the polarization are aligned from a gate to a channel, the threshold voltage is increased by deteriorating the ability to form an inversion layer of the channel, and when the directions of the polarization are aligned from the channel to the gate, the threshold voltage is decreased by improving the ability to form the inversion layer of the channel. In this case, a difference between two threshold voltages when the threshold voltage is maximally increased and when the threshold voltage is maximally decreased is referred to as a memory window. In the ferroelectric field effect transistor, the memory window is one of important performance indicators.

The polarization of the ferroelectric is determined by a write or erase operation. When a program (including writing and erasing) pulse is applied to the gate, an electric field is formed in the ferroelectric layer, and the polarization is aligned according to the magnitude and direction of the electric field. Thereafter, when the pulse application is stopped, the aligned polarization is maintained unlike general dielectrics. This may be represented by drawing a gap curve with the electric field and the polarization as a horizontal axis and a vertical axis, respectively. For this reason, the pulse application is inevitable in a program operation of the ferroelectric field effect transistor, and most of power is consumed when the pulse is applied. Accordingly, power consumption of the ferroelectric field effect transistor may be reduced by reducing the size and application time of the pulse. However, it is necessary to increase the magnitude and application time of the pulse in order to obtain a sufficient memory window, which is in deadlock with a method of reducing power consumption.

In studies that change the spacer of the existing ferroelectric field effect transistor, the material of the spacer has been changed from a silicon oxide-based low dielectric constant to a hafnium oxide-based high dielectric constant. Accordingly, a fringe electric field developed through the spacer has been suppressed, and an electric field of the gate dielectric film has been lowered. In particular, an electric field near the source and drain of the gate dielectric film has been significantly lowered. The electric field of the ferroelectric layer has been improved due to the lowered electric field of the gate dielectric film, and the polarization of the ferroelectric layer showed a greater value at the same write voltage. Accordingly, a high-k spacer ferroelectric field effect transistor may obtain a memory window that is larger than a low-k spacer field effect transistor, and there is an effect of reducing write energy due to a decrease in the write voltage in a situation where the same memory window is obtained. However, the high-k spacer increases a parasitic capacitance of the device, which is disadvantageous to the memory device that needs to perform a high-speed operation. In addition, the increased parasitic capacitance acts adversely on the write energy despite the decrease in the write voltage, and thus, when the thickness of the gate dielectric film is small, the amount of decrease in the write energy is not large.

### SUMMARY OF THE INVENTION

One technical problem to be solved by the present invention is to provide a ferroelectric field effect transistor equipped with a double spacer and a method of manufacturing the same.

Another technical problem to be solved by the present invention is to provide a ferroelectric field effect transistor having a suppression effect and a method of manufacturing the same.

Still another technical problem to be solved by the present invention is to provide a ferroelectric field effect transistor having a relocation effect and a method of manufacturing the same.

Still another technical problem to be solved by the present invention is to provide a ferroelectric field effect transistor having a suppression effect and a relocation effect and a method of manufacturing the same.

Still another technical problem to be solved by the present invention is to provide a ferroelectric field effect transistor in which an electric field of a gate dielectric layer decreases, whereas an electric field of a ferroelectric layer increases, and a method of manufacturing the same.

Still another technical problem to be solved by the present invention is to provide a ferroelectric field effect transistor having an improved memory window and a method of manufacturing the same.

Still another technical problem to be solved by the present invention is to provide a ferroelectric field effect transistor having a decreased parasitic capacitance and a method of manufacturing the same.

Still another technical problem to be solved by the present invention is to provide a ferroelectric field effect transistor capable of decreasing a write voltage and write energy, and a method of manufacturing the same.

The technical problems to be solved by the present invention are not limited to those described above.

To solve the above-described technical problems, the present invention provides a ferroelectric field effect transistor.

According to one embodiment, the ferroelectric field effect transistor may include: a body layer including a source region, a drain region spaced apart from the source region, and an intermediate region disposed between the source region and the drain region; a gate structure including a gate dielectric layer, a ferroelectric layer, and a gate electrode which are sequentially stacked on the intermediate region of the body layer; and a double spacer disposed on a side wall of the gate structure, in which the double spacer includes a high-k lower spacer and a low-k upper spacer disposed on the lower spacer.

According to one embodiment, when a voltage is applied to the gate electrode, a relatively high electric field may be formed in the ferroelectric layer and a relatively low electric field may be formed in the gate dielectric layer.

According to one embodiment, a boundary surface between the lower spacer and the upper spacer may be located adjacent to the ferroelectric layer of the gate structure.

According to one embodiment, a side wall of the lower spacer may make contact with both a side wall of the gate dielectric layer and a side wall of the ferroelectric layer.

According to one embodiment, a side wall of the upper spacer may make contact with both a side wall of the ferroelectric layer and a side wall of the gate electrode.

According to one embodiment, a lower surface of the lower spacer may make contact with any one of the source region and the drain region.

According to one embodiment, the lower spacer may include hafnium oxide (HfO₂), and the upper spacer may include silicon oxide (SiO₂).

According to one embodiment, the gate dielectric layer may include silicon oxide (SiO₂).

According to one embodiment, the ferroelectric layer may include hafnium zirconium oxide (HZO).

According to one embodiment, the lower spacer may have a thickness greater than 2.4 nm and less than 3.6 nm.

To solve the above-described technical problems, the present invention provides a method of manufacturing a ferroelectric field effect transistor.

According to one embodiment, the method of manufacturing a ferroelectric field effect transistor may include: preparing a substrate; forming a body layer on the substrate; forming a gate structure, in which a gate dielectric layer, a ferroelectric layer, and a gate electrode are sequentially stacked, on an intermediate region of the body layer; forming a source region and a drain region by injecting a dopant into a first region of the body layer adjacent to one side of the gate structure and a second region of the body layer adjacent to the other side of the gate structure; forming a high-k lower spacer on the source region and the drain region; and forming a low-k upper spacer on the lower spacer.

According to one embodiment, the lower spacer may be formed such that a level of an upper surface of the lower spacer is located between levels of an upper surface and a lower surface of the ferroelectric layer.

According to one embodiment, the forming of the gate structure may include: forming the gate dielectric layer on the body layer; forming the ferroelectric layer on the gate dielectric layer; forming the gate electrode on the ferroelectric layer; and etching the gate dielectric layer, the ferroelectric layer, and the gate electrode such that the first region and the second region of the body layer are exposed to an outside.

According to one embodiment, the forming of the lower spacer may include: forming a high-k material layer on the body layer such that the source region, the drain region, and the gate structure are conformally covered with the high-k material layer; and etching the high-k material layer such that an upper portion and a part of a side wall of the gate structure are exposed.

The ferroelectric field effect transistor according to the embodiment of the present invention may include: a body layer including a source region, a drain region spaced apart from the source region, and an intermediate region disposed between the source region and the drain region; a gate structure including a gate dielectric layer, a ferroelectric layer, and a gate electrode which are sequentially stacked on the intermediate region of the body layer; and a double spacer disposed on a side wall of the gate structure, in which the double spacer includes a high-k lower spacer and a low-k upper spacer disposed on the lower spacer.

Accordingly, the electric field of the gate dielectric layer may decrease, whereas the electric field of the ferroelectric layer may increase, so that a memory window may be improved, a parasitic capacitance may be decreased, and a write voltage and write energy may be decreased.

### BRIEF DESCRIPTION OF THE DRAWINGS

FIG. 1 is a flowchart for explaining a ferroelectric field effect transistor according to an embodiment of the present invention.

FIG. 2 is a view for specifically explaining a gate structure and a double spacer of the ferroelectric field effect transistor according to the embodiment of the present invention.

FIG. 3 is a flowchart for explaining a method of manufacturing the ferroelectric field effect transistor according to the embodiment of the present invention.

FIG. 4 is a schematic view for explaining step S100 in the method of manufacturing the ferroelectric field effect transistor according to the embodiment of the present invention.

FIG. 5 is a schematic view for explaining step S200 in the method of manufacturing the ferroelectric field effect transistor according to the embodiment of the present invention.

FIG. 6 is a flowchart for more specifically explaining step S300 in the method of manufacturing the ferroelectric field effect transistor according to the embodiment of the present invention.

FIG. 7 is a schematic view for explaining step S310 in the method of manufacturing the ferroelectric field effect transistor according to the embodiment of the present invention.

FIG. 8 is a schematic view for explaining step S320 in the method of manufacturing the ferroelectric field effect transistor according to the embodiment of the present invention.

FIG. 9 is a schematic view for explaining step S330 in the method of manufacturing the ferroelectric field effect transistor according to the embodiment of the present invention.

FIG. 10 is a schematic view for explaining step S335 in the method of manufacturing the ferroelectric field effect transistor according to the embodiment of the present invention.

FIG. 11 is a schematic view for explaining step S340 in the method of manufacturing the ferroelectric field effect transistor according to the embodiment of the present invention.

FIG. 12 is a schematic view for explaining step S400 in the method of manufacturing the ferroelectric field effect transistor according to the embodiment of the present invention.

FIG. 13 is a flowchart for more specifically explaining step S500 in the method of manufacturing the ferroelectric field effect transistor according to the embodiment of the present invention.

FIG. 14 is a schematic view for explaining step S510 in the method of manufacturing the ferroelectric field effect transistor to the embodiment of the present invention.

FIG. 15 is a schematic view for explaining step S520 in the method of manufacturing the ferroelectric field effect transistor according to the embodiment of the present invention.

FIG. 16 is a flowchart for more specifically explaining step S600 in the method of manufacturing the ferroelectric field effect transistor according to the embodiment of the present invention.

FIG. 17 is a schematic view for explaining step S610 in the method of manufacturing the ferroelectric field effect transistor according to the embodiment of the present invention.

FIG. 18 is a schematic view for explaining step S620 in the method of manufacturing the ferroelectric field effect transistor according to the embodiment of the present invention.

FIG. 19 is a schematic view for explaining step S700 in the method of manufacturing the ferroelectric field effect transistor according to the embodiment of the present invention.

FIGS. 20(a), 20(b), 20(c) and 21 are views comparing memory windows of ferroelectric field effect transistors according to an experimental example and comparative examples of the present invention.

FIG. 22 is a view for explaining an electric field distribution of the ferroelectric field effect transistors according to the experimental example and the comparative examples of the present invention.

FIGS. 23 and 24 are views for explaining electric fields shown in gate dielectric layers of the ferroelectric field effect transistors according to the experimental example and the comparative examples of the present invention.

FIG. 25 is a view for explaining a state where information of FIG. 23 is recorded together with a portion of the gate dielectric layer of FIG. 22.

FIGS. 26 and 27 are views for explaining electric fields and polarization shown in ferroelectric layers of the ferroelectric field effect transistors according to the experimental example and the comparative examples of the present invention.

FIGS. 28(a), 28(b) and 29 are views comparing characteristics according to a thickness of a lower spacer of the ferroelectric field effect transistor according to the experimental example of the present invention.

### DETAILED DESCRIPTION OF THE INVENTION

Hereinafter, preferred embodiments of the present invention will be described in detail with reference to the accompanying drawings. However, the present invention may be embodied in different forms and should not be construed as limited to the embodiments set forth herein. Rather, the embodiments introduced herein are provided so that the disclosed contents may be thorough and complete and the spirit of the present invention may be sufficiently conveyed to those skilled in the art.

In the present specification, it will be understood that when an element is referred to as being “on” another element, it can be formed directly on the other element or intervening elements may be present. In the drawings, the thicknesses of layers and regions are exaggerated for clarity.

In addition, it will be also understood that although the terms first, second, third, etc. may be used herein to describe various elements, these elements should not be limited by these terms. These terms are only used to distinguish one element from another element. Thus, a first element in some embodiments may be termed a second element in other embodiments without departing from the teachings of the present invention. Embodiments explained and illustrated herein include their complementary counterparts. As used herein, the term “and/or” includes any and all combinations of one or more of the associated listed elements.

The singular expression also includes the plural meaning as long as it does not differently mean in the context. In addition, the terms “comprise”, “have” etc., of the description are used to indicate that there are features, numbers, steps, elements, or combination thereof, and they should not exclude the possibilities of combination or addition of one or more features, numbers, operations, elements, or a combination thereof. Furthermore, it will be understood that when an element is referred to as being “connected” or “coupled” to another element, it may be directly connected or coupled to the other element or intervening elements may be present.

In addition, when detailed descriptions of related known functions or constitutions are considered to unnecessarily cloud the gist of the present invention in describing the present invention below, the detailed descriptions will not be included.

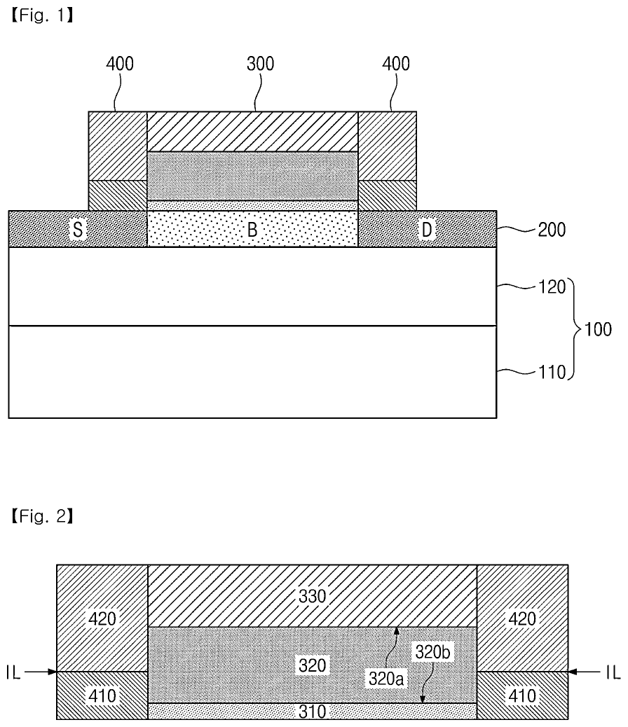

FIG. 1 is a flowchart for explaining a ferroelectric field effect transistor according to an embodiment of the present invention, and FIG. 2 is a view for specifically explaining a gate structure and a double spacer of the ferroelectric field effect transistor according to the embodiment of the present invention.

Referring to FIGS. 1 and 2, the ferroelectric field effect transistor to the embodiment may include a substrate 100, a body layer 200, a gate structure 300, and a double spacer 400. Hereinafter, the respective components will be described.

According to one embodiment, the substrate 100 may be a silicon semiconductor substrate. More specifically, the substrate 100 may be a substrate in which a silicon oxide (SiO₂) layer 120 is formed on a silicon (Si) substrate 110. Alternatively, according to another embodiment, the substrate 100 may be a compound semiconductor substrate. Alternatively, according to still another embodiment, the substrate 100 may be a glass substrate. Alternatively, according to still another embodiment, the substrate 100 may be a plastic substrate. The type of the substrate 100 is not limited.

The body layer 200 may be disposed on the substrate 100. For example, the body layer 200 may include silicon (Si). According to one embodiment, the body layer 200 may include a source region S, a drain region D spaced apart from the source region S, and an intermediate region B disposed between the source region S and the drain region D. For example, the source region S may be a region in which a first dopant is injected into the body layer 200, and the drain region D may be a region in which a second dopant is injected into the body layer 200. Alternatively, the intermediate region B may be a region into which no dopant is injected.

The gate structure 300 may be disposed on the intermediate region B of the body layer 200. The gate structure 300 may have a structure in which a gate dielectric layer 310, a ferroelectric layer 320, and a gate electrode 330 are sequentially stacked. That is, the gate dielectric layer 310 may be disposed on the intermediate region B of the body layer 200, the ferroelectric layer 320 may be disposed on the gate dielectric layer 310, and the gate electrode 330 may be disposed on the ferroelectric layer 320. According to one embodiment, the gate dielectric layer 310 may include silicon oxide (SiO₂). According to one embodiment, the ferroelectric layer 320 may include hafnium zirconium oxide (HZO) or a material in which hafnium oxide is doped with silicon. According to one embodiment, the gate electrode 330 may include titanium nitride (TiN). In addition, although not shown, a capping layer including poly-Si may be disposed on the gate electrode 330.

The double spacer 400 may be disposed on the source region S and/or the drain region D of the body layer 200. In addition, the double spacer 400 may be disposed on a side wall of the gate structure 300.

The double spacer 400 may include a lower spacer 410 and an upper spacer 420 disposed on the lower spacer 410. According to one embodiment, the lower spacer 410 may include a high-k material. For example, the lower spacer 410 may include hafnium oxide (HfO₂). Alternatively, the upper spacer 420 may include a low-k material. For example, the upper spacer 420 may include silicon oxide (SiO₂).

According to one embodiment, a boundary surface IL between the lower spacer 410 and the upper spacer 420 may be located adjacent to the ferroelectric layer 200 of the gate structure 300. That is, a level of the boundary surface IL between the lower spacer 410 and the upper spacer 420 may be located between levels of an upper surface 320a and a lower surface 320b of the ferroelectric layer 320.

In addition, a side wall of the lower spacer 410 may make contact with both a side wall of the gate dielectric layer 310 and a side wall of the ferroelectric layer 320, and a side wall of the upper spacer 420 may make contact with the side wall of the ferroelectric layer 320 and a side wall of the gate electrode 330.

Through the structure as described above, in the ferroelectric field effect transistor according to the embodiment, an electric field of the gate dielectric layer 310 may decrease, but an electric field of the ferroelectric layer 320 may increase. Accordingly, a memory window may be improved, a parasitic capacitance may be decreased, and a write voltage and write energy may be decreased.

More specifically, the high-k lower spacer 410 may suppress a fringe electric field, so that it is possible to suppress the increase in the electric field of the gate dielectric layer 310 adjacent to the source region S and the drain region D. In describing the present specification, the above-described effect is defined as a “suppression effect”.

In addition, as the level of the boundary surface IL between the lower spacer 410 and the upper spacer 420 is located between the levels of the upper surface 320a and the lower surface 320b of the ferroelectric layer 320, the fringe electric field caused by the upper spacer 420 may be developed to a high value around the ferroelectric layer 320, so that the electric field of the ferroelectric layer 320 may be increased. In describing the present specification, the above-described effect is defined as a “relocation effect”.

That is, in the ferroelectric field effect transistor according to the embodiment, since the suppression effect and the relocation effect may be applied, the electric field of the gate dielectric layer 310 may decrease, whereas the electric field of the ferroelectric layer 320 may increase. Accordingly, a memory window may be improved, a parasitic capacitance may be decreased, and a write voltage and write energy may be decreased.

Hereinabove, the ferroelectric field effect transistor according to the embodiment of the present invention have been described. Hereinafter, a method of manufacturing a ferroelectric field effect transistor according to the embodiment of the present invention will be described.

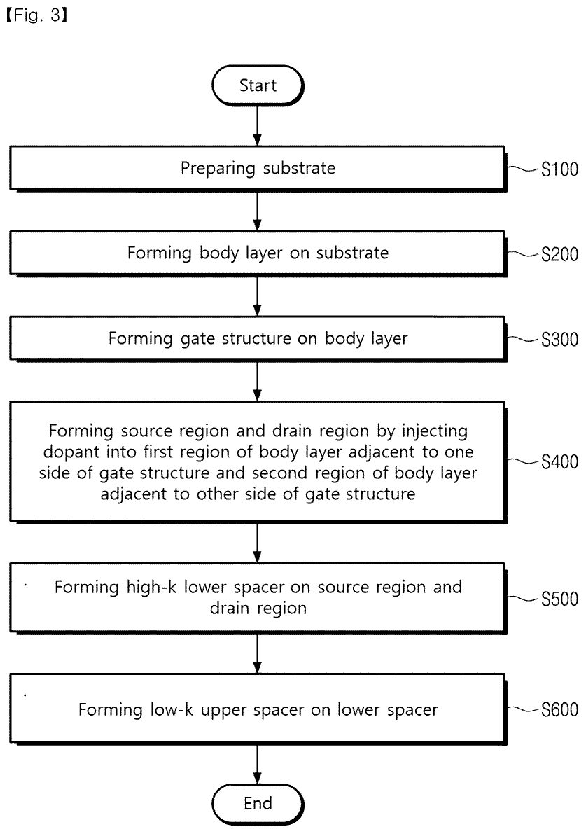

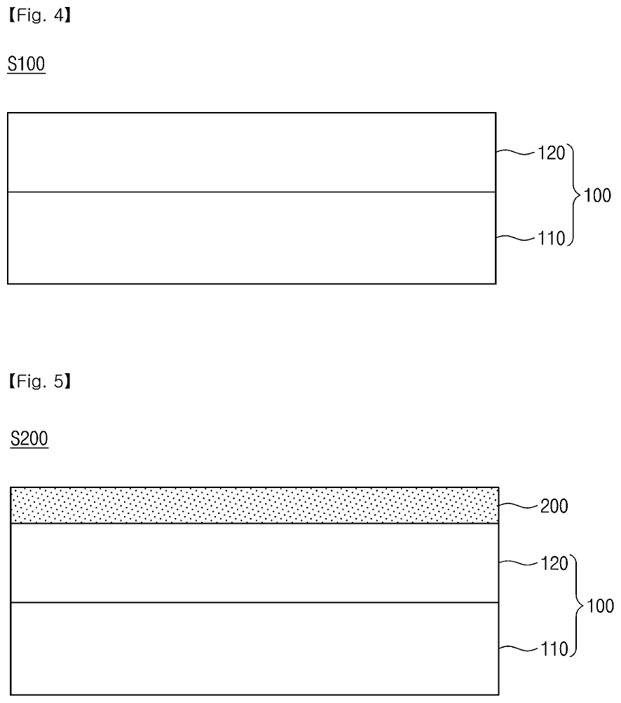

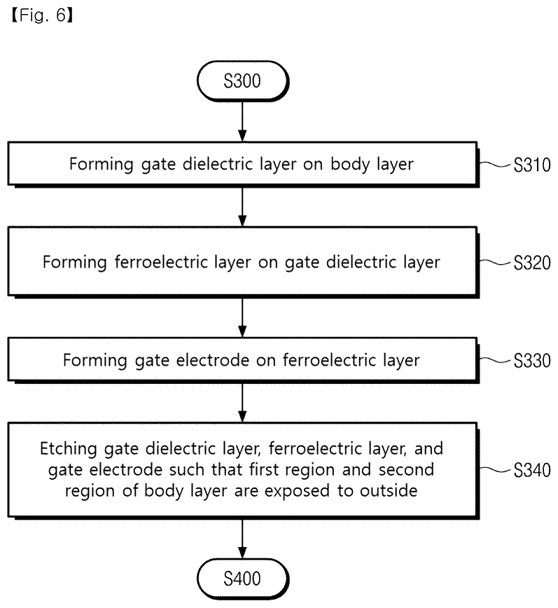

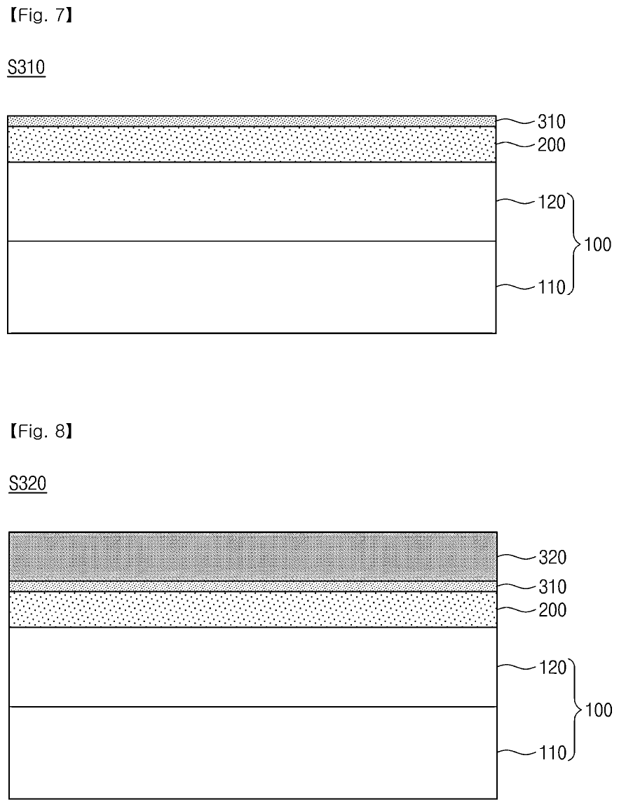

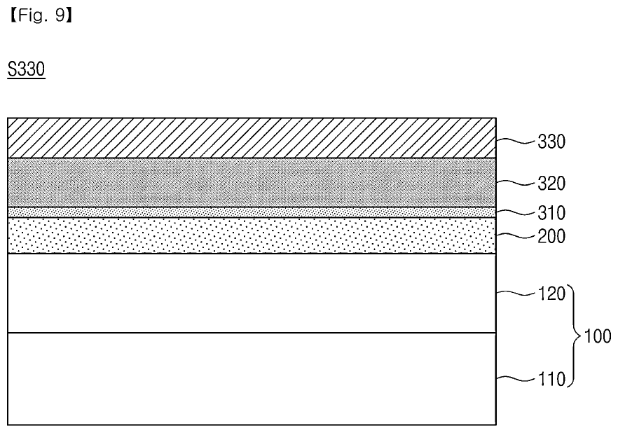

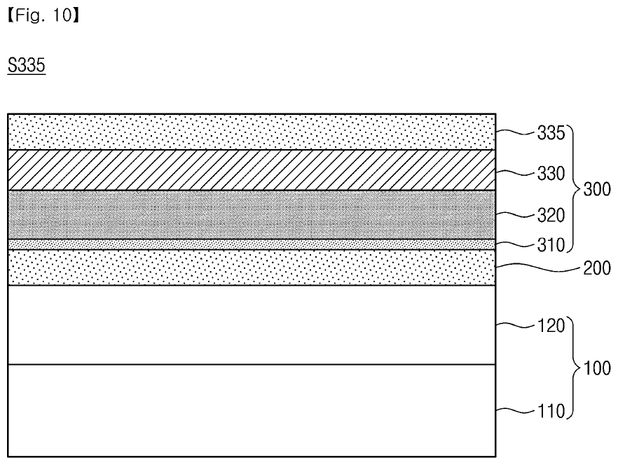

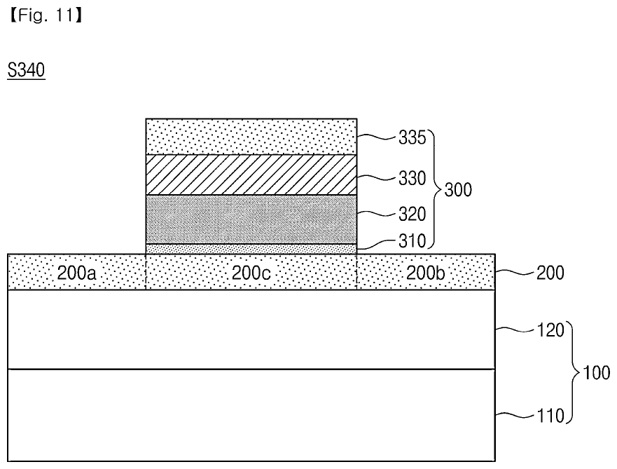

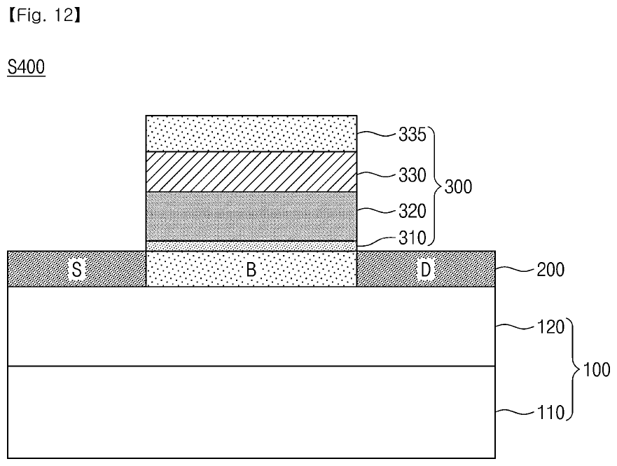

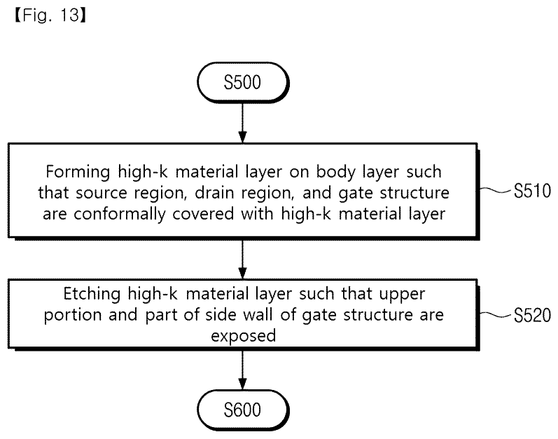

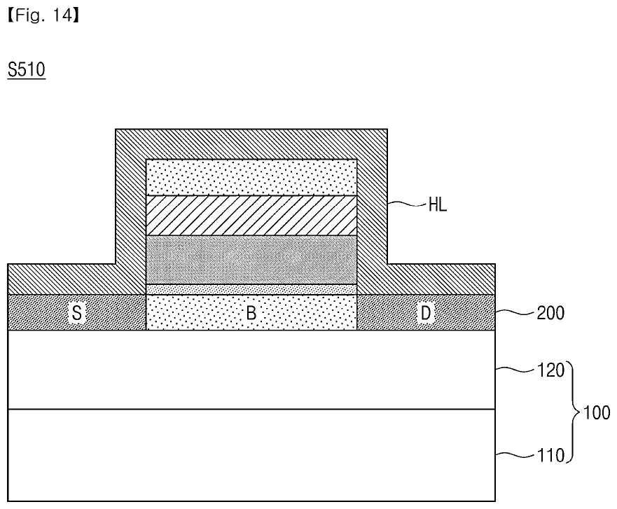

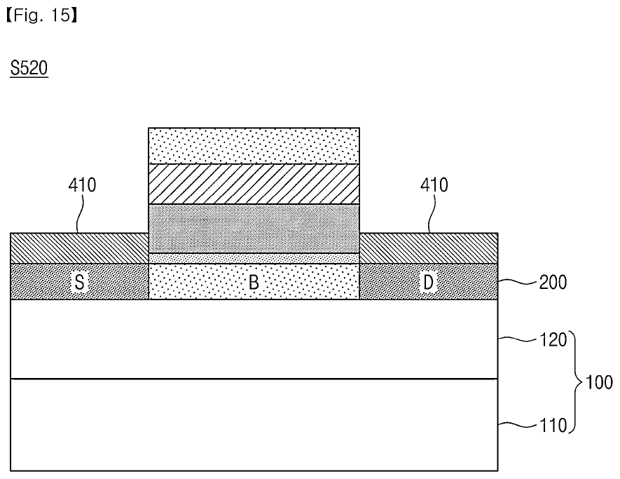

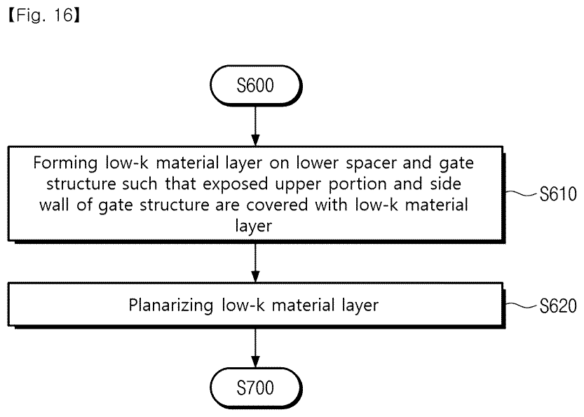

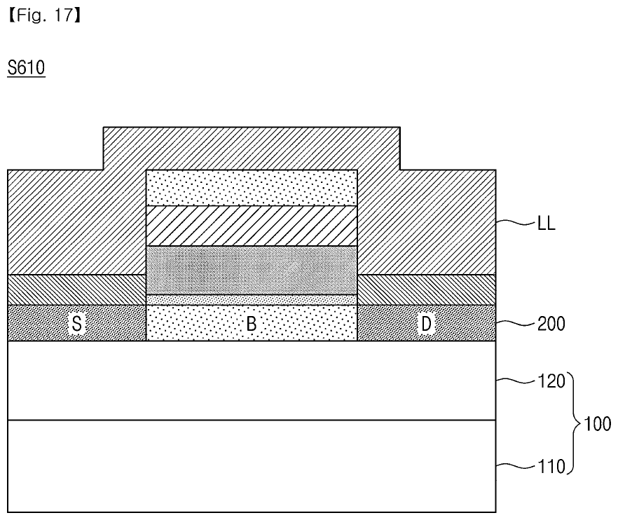

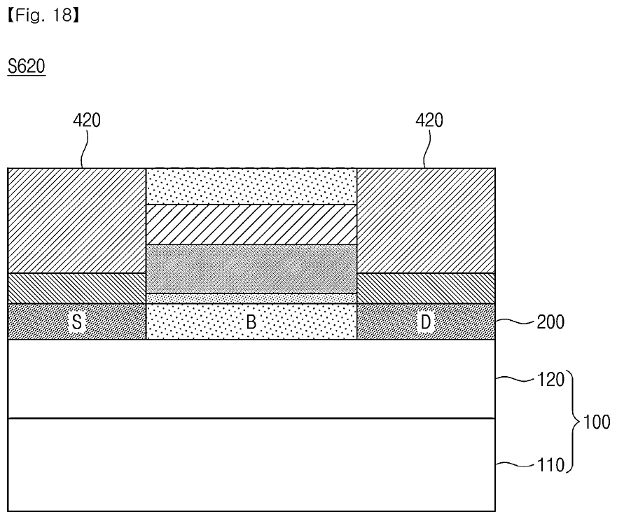

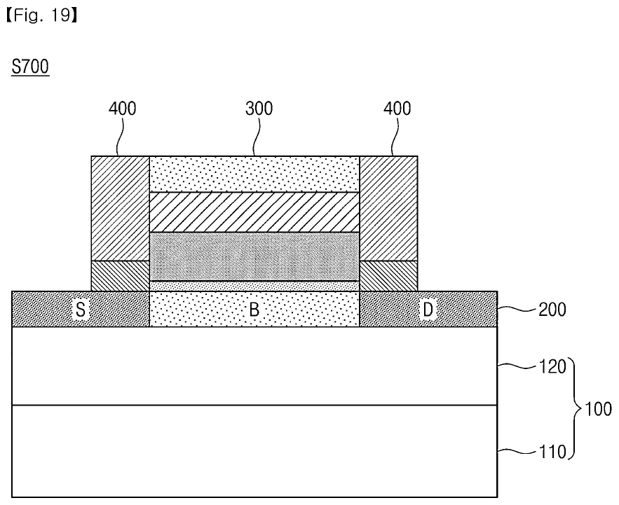

FIG. 3 is a flowchart for explaining a method of manufacturing the ferroelectric field effect transistor according to the embodiment of the present invention, FIG. 4 is a schematic view for explaining step S100 in the method of manufacturing the ferroelectric field effect transistor according to the embodiment of the present invention, FIG. 5 is a schematic view for explaining step S200 in the method of manufacturing the ferroelectric field effect transistor according to the embodiment of the present invention, FIG. 6 is a flowchart for more specifically explaining step S300 in the method of manufacturing the ferroelectric field effect transistor according to the embodiment of the present invention, FIG. 7 is a schematic view for explaining step S310 in the method of manufacturing the ferroelectric field effect transistor according to the embodiment of the present invention, FIG. 8 is a schematic view for explaining step S320 in the method of manufacturing the ferroelectric field effect transistor according to the embodiment of the present invention, FIG. 9 is a schematic view for explaining step S330 in the method of manufacturing the ferroelectric field effect transistor according to the embodiment of the present invention, FIG. 10 is a schematic view for explaining step S335 in the method of manufacturing the ferroelectric field effect transistor according to the embodiment of the present invention, FIG. 11 is a schematic view for explaining step S340 in the method of manufacturing the ferroelectric field effect transistor according to the embodiment of the present invention, FIG. 12 is a schematic view for explaining step S400 in the method of manufacturing the ferroelectric field effect transistor according to the embodiment of the present invention, FIG. 13 is a flowchart for more specifically explaining step S500 in the method of manufacturing the ferroelectric field effect transistor according to the embodiment of the present invention, FIG. 14 is a schematic view for explaining step S510 in the method of manufacturing the ferroelectric field effect transistor according to the embodiment of the present invention, FIG. 15 is a schematic view for explaining step S520 in the method of manufacturing the ferroelectric field effect transistor according to the embodiment of the present invention, FIG. 16 is a flowchart for more specifically explaining step S600 in the method of manufacturing the ferroelectric field effect transistor according to the embodiment of the present invention, FIG. 17 is a schematic view for explaining step S610 in the method of manufacturing the ferroelectric field effect transistor according to the embodiment of the present invention, FIG. 18 is a schematic view for explaining step S620 in the method of manufacturing the ferroelectric field effect transistor according to the embodiment of the present invention, FIG. 19 is a schematic view for explaining step S700 in the method of manufacturing the ferroelectric field effect transistor according to the embodiment of the present invention.

Referring to FIGS. 3 and 4, a substrate 100 may be prepared (S100). According to one embodiment, the substrate 100 may be a silicon semiconductor substrate. More specifically, the substrate 100 may be a substrate in which a silicon oxide (SiO₂) layer 120 is formed on a silicon (Si) substrate 110. Alternatively, according to another embodiment, the substrate 100 may be a compound semiconductor substrate. Alternatively, according to still another embodiment, the substrate 100 may be a glass substrate. Alternatively, according to still another embodiment, the substrate 100 may be a plastic substrate. The type of the substrate 100 is not limited.

Referring to FIGS. 3 and 5, a body layer 200 may be formed on the substrate 100 (S200). According to one embodiment, the body layer 200 may include silicon (Si).

Referring to FIGS. 6 and 7, a ferroelectric layer 310 may be formed on the gate electrode 200 (S310). According to one embodiment, the gate dielectric layer 310 may include silicon oxide (SiO₂). According to one embodiment, the gate dielectric layer 310 may be formed by rapid thermal oxidation of the body layer 200.

Referring to FIGS. 6 and 8, a ferroelectric layer 320 may be formed on the gate dielectric layer 310 (S320). According to one embodiment, the ferroelectric layer 320 may include hafnium zirconium oxide (HZO). Alternatively, according to another embodiment, the ferroelectric layer 320 may be a material in which hafnium oxide is doped with silicon. According to one embodiment, the ferroelectric layer 320 may be formed by atomic layer deposition (ALD).

Referring to FIGS. 6 and 9, a gate electrode 330 may be formed on the ferroelectric layer 320. According to one embodiment, the gate electrode 330 may include titanium nitride (TiN). According to one embodiment, the gate electrode 330 may be formed by plasma vapor deposition (PVD).

Referring to FIG. 10, a capping layer 335 may be formed on the gate electrode 330 (S335). Accordingly, a gate structure 300, in which the gate dielectric layer 310, the ferroelectric layer 320, the gate electrode 330, and the capping layer 335 are sequentially stacked, may be formed on the body layer 200. According to one embodiment, the capping layer 335 may include poly-Si. According to one embodiment, the gate electrode 335 may be formed by chemical vapor deposition (CVD).

Referring to FIGS. 6 and 11, the gate dielectric layer 310, the ferroelectric layer 320, the gate electrode 330, and the capping layer 335 may be etched such that a first region 200a and a second region 200b of the body layer 200 are exposed to the outside. Accordingly, the first region 200a and the second region 200b of the body layer 200 may be exposed to the outside, whereas a region 200c between the first region 200a and the second region 200b may not be exposed by the gate structure 300. According to one embodiment, the first region 200a may be a region adjacent to one side of the body layer 200. On the other hand, the second region 200b may be a region adjacent to the other side of the body layer 200.

Referring to FIGS. 3 and 12, dopants may be injected into the first region 200a of the body layer 200 adjacent to one side of the gate structure 300 and the second region 200b of the body layer 200 adjacent to the other side of the gate structure 300, respectively. Therefore, a source region S and a domain region D may be formed (S400). In other words, the first region 200a may be converted into the source region S by injecting the dopant into the first region 200a, and the second region 200b may be converted into the drain region D by injecting the dopant into the second region 200b. The region 200c between the first region 200a and the second region 200b may maintain the original state of the body layer 200 because the dopant is not injected, which may be defined as an intermediate region B.

Referring to FIGS. 13 and 14, a high-k material layer HL may be formed on the body layer 200 such that the source region S, the drain region D, and the gate structure 300 are conformally covered with the high-k material layer HL (S510). According to one embodiment, the high-k material layer HL may include hafnium oxide (HfO₂). According to one embodiment, the high-k material layer HL may be formed by atomic layer deposition (ALD).

Referring to FIGS. 13 and 15, the high-k material layer HL may be etched such that an upper portion and a part of the side wall of the gate structure 300 are exposed (S520). Accordingly, the high-k material layer HL may remain only on the source region S and the drain region D of the body layer 200, and the remaining high-k material layer HL may be defined as a lower spacer 410. According to one embodiment, the lower spacer 410 may be formed such that a level of an upper surface of the lower spacer is located between levels of an upper surface and a lower surface of the ferroelectric layer 320.

Referring to FIGS. 16 and 17, a low-k material layer LL may be formed on the lower spacer 410 and the gate structure 300 such that the exposed upper portion and side wall of the gate structure 300 are covered with the low-k material layer LL (S610). According to one embodiment, the low-k material layer LL may include silicon oxide (SiO₂). According to one embodiment, the low-k material layer LL may be formed by atomic layer deposition (ALD).

Referring to FIGS. 16 and 18, the low-k material layer LL may be planarized (S620). According to one embodiment, the low-k material layer LL disposed on the gate structure 300 may be removed, and a level of the upper surface of the low-k material layer LL may be planarized to be the same as the level of the upper surface of the gate structure 300. Accordingly, the low-k material layer LL may remain only on the lower spacer 410, and the low dielectric material layer LL remaining on the lower spacer 410 may be defined as an upper spacer 420.

Referring to FIG. 19, the upper spacer 420 and the lower spacer 410 may be etched to expose a part of the source region S and a part of the drain region D (S700). Accordingly, the ferroelectric field effect transistor according to the embodiment may be manufactured.

Hereinabove, the ferroelectric field effect transistor and the method of manufacturing the ferroelectric field effect transistor according to the embodiment of the present invention have been described. Hereinafter, specific experimental examples and characteristic evaluation results of the ferroelectric field effect transistor according to the embodiment of the present invention will be described.

### Experimental Example 1: Manufacture of Ferroelectric Field Effect Transistor

A ferroelectric field effect transistor was manufactured by the method described with reference to FIGS. 3 to 19. Materials used as respective components of the ferroelectric field effect transistor are summarized through <Table 1> below, and various parameters of the ferroelectric field effect transistor according to an experimental example are summarized through <Table 2>. below.

TABLE 1

| Classification | Material |
|---|---|
| Substrate | SOI (Si/SiO₂) |
| Body layer | Si |
| Gate dielectric layer | SiO₂ |
| Ferroelectric layer | HZO |
| Gate electrode | TiN |
| Lower spacer | HfO₂ |
| Upper spacer | SiO₂ |

TABLE 2

| Parameter | Value |
|---|---|
| Length of gate electrode (L_{g}, | 20 |
| nm) | |
| Width of channel (W_{ch}, nm) | 20 |
| Thickness of channel (T_{ch}, nm) | 5 |
| Thickness of substrate (T_{BOX}, nm) | 25 |
| *** (Lₛₚ, nm) | 10 |
| Thickness of gate dielectric | 0.6 |
| layer (Tₒₓ, nm) | |
| Thickness of ferroelectric | 5.5 |
| layer (T_{fr}, nm) | |
| WF (eV) | 4.38 |
| S/D doping (cm⁻³) | 4e20 |
| Channel doping (cm⁻³) | 2e14 |
| Substrate doping (cm⁻³) | 2e20 |
| Remanent polarization (Pᵣ, | 19.5 |
| μC/cm²) | |
| Saturation polarization (Ps, | 19.8 |
| μC/cm²) | |
| Coercive electric field (E_{c}, | 1.45 |
| MV/cm) | |

### Experimental Example 2: Confirmation of Memory Window of Ferroelectric Field Effect Transistor

To confirm memory window superiority of the ferroelectric field effect transistor according to the experimental example, the ferroelectric field effect transistor according to the experimental was compared with the example ferroelectric field effect transistors according to comparative examples. Specifically, as the ferroelectric field effect transistor according to Comparative Example 1, a transistor having the same structure as the ferroelectric field effect transistor according to the above-described experimental example and using a high-k single spacer (HfO₂) instead of a double spacer was prepared. In addition, as the ferroelectric field effect transistor according to Comparative Example 2, a transistor having the same structure as the ferroelectric field effect transistor according to the above-described experimental example and using a low-k single spacer (SiO₂) instead of a double spacer was prepared. In describing Experimental Example 2, the ferroelectric field effect transistor according to the experimental example is defined as D-FeFET, the ferroelectric field effect transistor according to Comparative Example 1 is defined as H-FeFET, and the ferroelectric field effect transistor according to Comparative Example 2 is defined as L-FeFET.

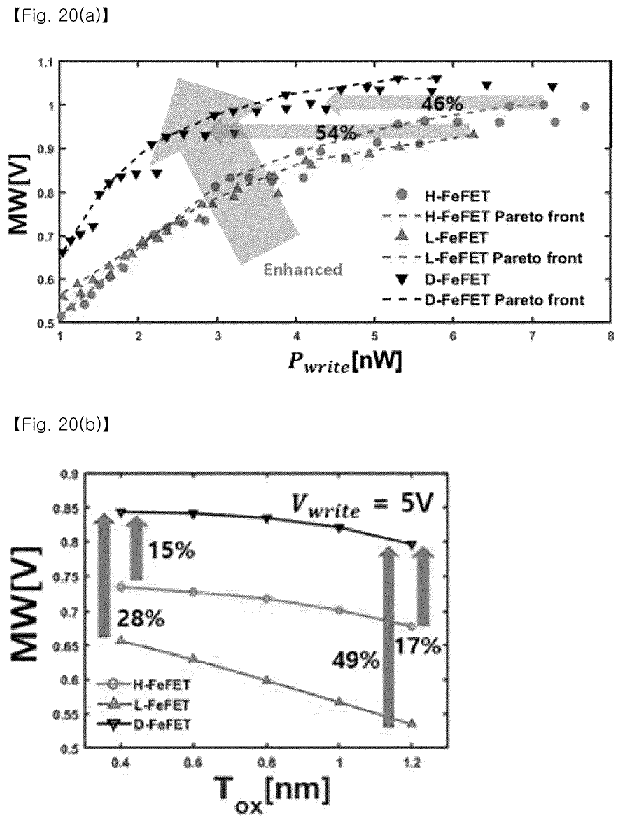

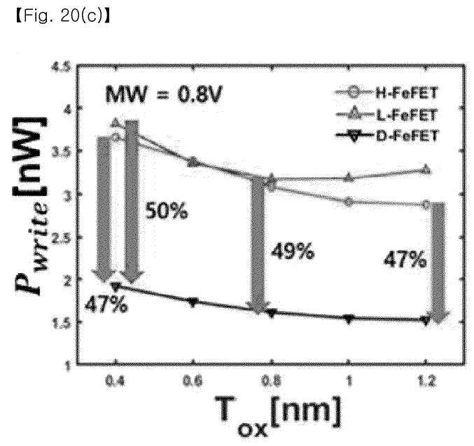

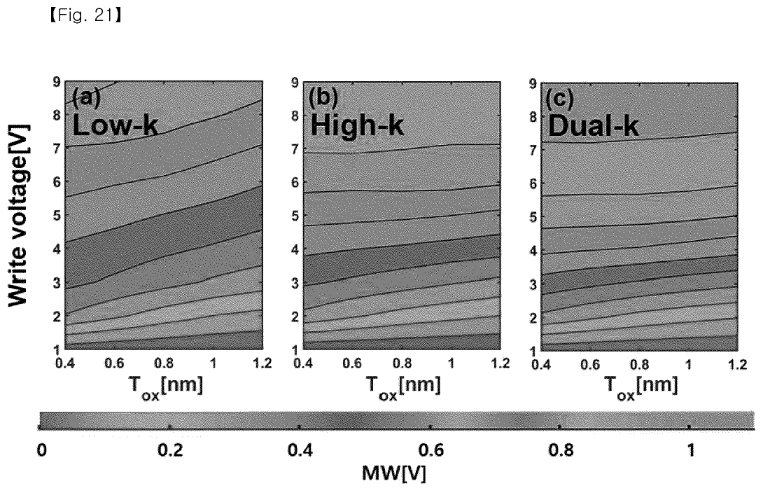

FIGS. 20(a), 20(b), 20(c) and 21 are views comparing memory windows of ferroelectric field effect transistors according to the experimental example and the comparative examples of the present invention.

FIG. 20(a) shows a memory window, a write energy distribution, and a pareto front of each of the ferroelectric transistor field effect transistors according to the experimental example and the comparative examples, FIG. 20(b) shows comparison of memory windows according to a thickness of a gate dielectric layer of each of the ferroelectric field effect transistors at the same write voltage, and FIG. 20(c) shows comparison of write energy consumption according to a thickness of the gate dielectric layer of each of the ferroelectric field effect transistors in order to secure the same memory window.

In addition, a memory window obtained under the condition of a thickness of a gate dielectric layer of 0.6 nm and a write voltage of 5 V, a maximum memory window that may be obtained, write energy for obtaining a memory window at 0.8 V, and write energy for obtaining a maximum memory window were measured from each ferroelectric field effect transistor, and the measured results thereof are summarized in <Table 3> below.

TABLE 3

| | Comparative | Comparative | Experimental | |
|---|---|---|---|---|
| | Example 2 | Example 1 | Example | Enhancement |
| Classification | (L-FeFET) | (H-FeFET) | (D-FeFET) | [L/H] |
| MW (@V_{write} = | 0.63 | 0.73 | 0.84 | 33.3%/15.1% |
| 5 V) [V] | | | | |
| MW | 0.90 | 0.98 | 1.05 | 16.7%/7.14% |
| (maximum) | | | | |
| [V] | | | | |
| E_{write} (@MW = | 3.35 | 3.38 | 1.74 | 48.1%/48.5% |
| 0.8 V) | | | | |
| [nJ] | | | | |
| E_{write} | 5.31 | 8.34 | 6.42 | −20.9%/23.0% |
| (@maimum | | | | |
| MW) [nJ] | | | | |

As can be seen from FIGS. 20(a) to 20(c), it can be seen that the ferroelectric field effect transistor (double spacer) according to the experimental example may acquire the highest memory window at the same write voltage as compared to the ferroelectric field effect transistors (single spacers) according to the comparative examples, and the same memory window may be secured at the lowest write voltage. In addition, it can be seen that the pareto front between the memory window and the write energy is expanded in the ferroelectric field effect transistor (double spacer) according to the experimental example as compared to the ferroelectric field effect transistors (single spacers) according to the comparative examples.

More specifically, as can be seen from FIG. 20(a), it can be seen that the ferroelectric field effect transistor according to the experimental example has the widest pareto front. In addition, in the case of the maximum memory window that may be obtained from the ferroelectric field effect transistors (single spacers) according to the comparative examples, it can be seen that the ferroelectric field effect transistor (double spacer) according to the experimental example may be obtained using write energy that is decreased by 46% and 54%.

As can be seen in FIG. 20(b), it can be quantitatively seen that the ferroelectric field effect transistor (double spacer) according to the experimental example has a memory window that is improved by at least 15% as compared to the ferroelectric field effect transistors (single spacers) according to the comparative examples, and particularly, has a memory window that is improved by 28% to 49% as compared to the ferroelectric field effect transistor according to Comparative Example 2 (low-k single spacer).

In addition, in the ferroelectric field effect transistor (low-k single spacer) according to Comparative Example 2 in which a suppression effect is not effective, it can be seen that the memory window is clearly attenuated according to the thickness of the gate dielectric layer. On the other hand, it can be seen that the ferroelectric field effect transistor (high-k single spacer) according to Comparative Example 1 and the ferroelectric field effect transistor (double spacer) according to the experimental example have an effective suppression effect, so that the memory window is gradually attenuated according to the thickness of the gate dielectric film, and the two structures are attenuated in a similar tendency.

As can be seen in FIG. 20(c), it can be seen that the ferroelectric field effect transistor (double spacer) according to the experimental example has a lowered write voltage, the write energy is significantly reduced by the lowered gate capacitance as compared to the ferroelectric field effect transistor (high-k single spacer) according to Comparative Example 1, and the write energy is decreased by 47% or greater as compared to the ferroelectric field effect transistors (single spacers) according to the comparative examples.

It can be seen that the ferroelectric field effect transistor (high-k single spacer) according to Comparative Example 1 has a little decrease in write energy at a thickness of a gate dielectric layer of 0.8 nm or less as compared to the ferroelectric field effect transistor (low-k single spacer) according to Comparative Example 2, and at 1 nm or greater, the write voltage increase dominantly acts as compared to a decrease in gate capacitance of the ferroelectric field effect transistor (low-k single spacer) according to Comparative Example 2, so that the write energy decreases only 11.9% due to the increase in write energy.

Referring to FIG. 21, a read operation is performed after a write operation, the read operation is performed after an erase operation, a threshold voltage according to a state of the transistor is measured during the read operation, and a size of the memory window according to the thickness of the gate dielectric layer and a magnitude of the write voltage is indicated by a contour. In more detail, FIG. 21(a) shows a memory window size of the ferroelectric field effect transistor according to Comparative Example 2, FIG. 21(b) shows a memory window size of the ferroelectric field effect transistor according to Comparative Example 1, and FIG. 21(c) shows a memory window size of the ferroelectric field effect transistor according to the experimental example.

As can be seen from FIGS. 21(a) to 21(c), in the field effect transistor (low-k single spacer) according to Comparative Example 2, it can be seen that the memory window is clearly attenuated according to the thickness of the gate dielectric layer as compared to the other two structures. This is because the electric field of the gate dielectric layer varies depending on the thickness of the gate dielectric layer due to characteristics of the low-k single spacer structure in which the suppression effect is not effective.

In the two structures in which the suppression effect is effective (Comparative Example 1 and the experimental example), it can be seen that the influence on the memory window according to the thickness of the gate dielectric layer is reduced. In addition, the memory window may be obtained the highest in the ferroelectric field effect transistor (double spacer) according to the experimental example due to the relocation effect, and it can be seen that a change in the memory window according to an increase in the write voltage is the clearest. It can be seen that the ferroelectric field effect transistor (double spacer) according to the experimental example is the only one having a memory window at 1 V or greater, the ferroelectric field (low-k single spacer) according to effect transistor Comparative Example 1 requires a write voltage of 7-8 V to have a memory window at 0.8 V, the ferroelectric field effect transistor (high-k single spacer) according to Comparative Example 2 requires a write voltage of 6 V, and the ferroelectric field effect transistor (double spacer) according to the experimental example requires a write voltage of 5 V.

### Experimental Example 3: Confirmation of Electric Field Distribution and Polarization of Ferroelectric Field Effect Transistor

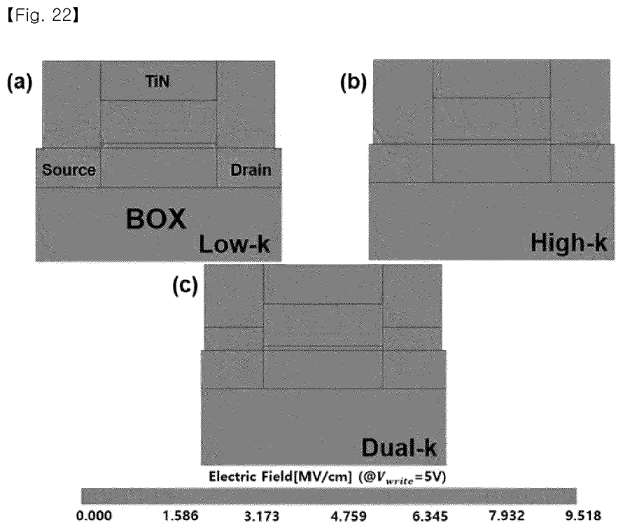

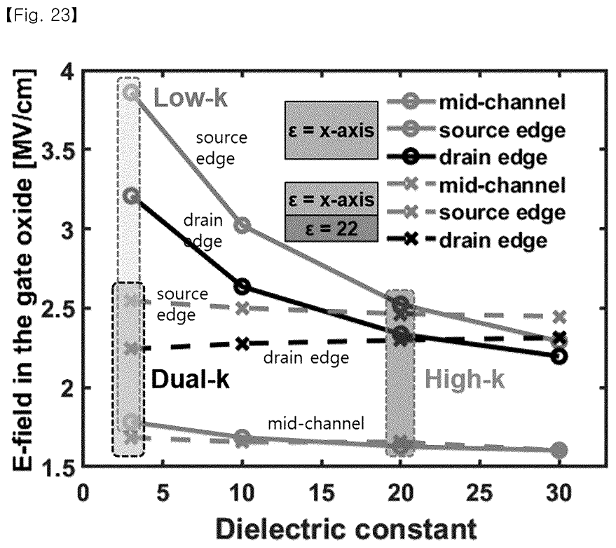

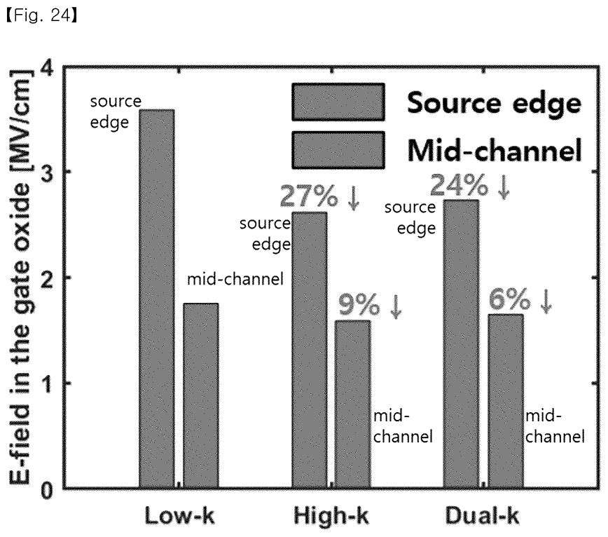

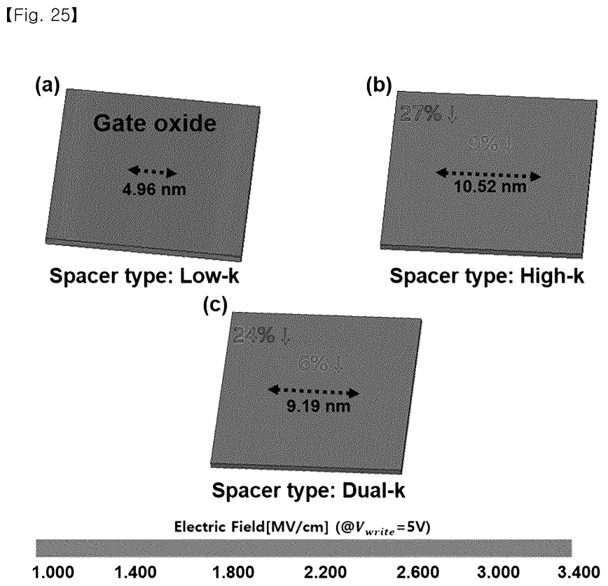

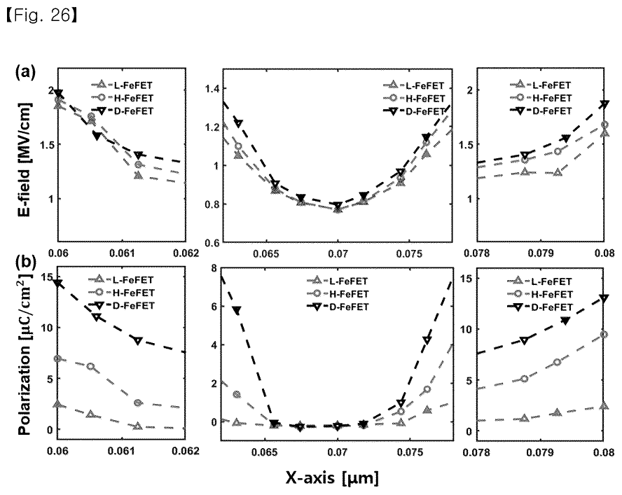

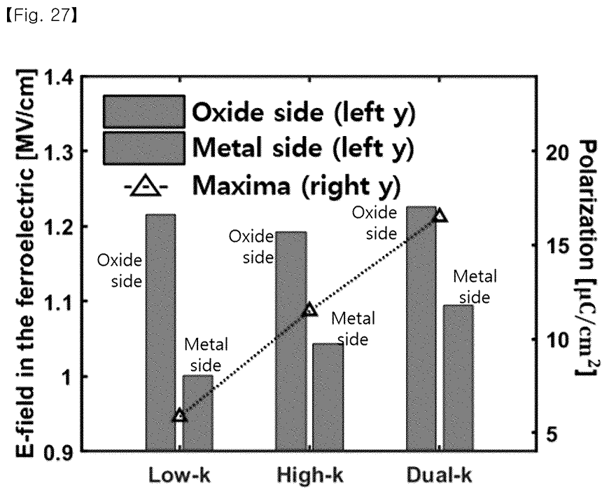

FIG. 22 is a view for explaining an electric field distribution of the ferroelectric field effect transistors according to the experimental example and the comparative examples of the present invention, FIGS. 23 and 24 are views for explaining electric fields shown in gate dielectric layers of the ferroelectric field effect transistors according to the experimental example and the comparative examples of the present invention, FIG. 25 is a view for explaining a state where information of FIG. 23 is recorded together with a portion of the gate dielectric layer of FIG. 22, and FIGS. 26 and 27 are views for explaining electric fields and polarization shown in ferroelectric layers of the ferroelectric field effect transistors according to the experimental example and the comparative examples of the present invention.

FIG. 22 shows an electric field distribution during the application of the write voltage of the ferroelectric field effect transistors according to the experimental example and the comparative examples. In more detail, FIG. 22(a) shows an electric field distribution of the ferroelectric field effect transistor according to Comparative Example 2, FIG. 22(b) shows an electric field distribution of the ferroelectric field effect transistor according to Comparative Example 1, and FIG. 22(c) shows an electric field distribution of the ferroelectric field effect transistor according to the experimental example.

FIGS. 22 to 25 show an electric field of the gate dielectric layer that is divided into the vicinity of a source/drain and the vicinity of the center of a channel while changing a dielectric constant, and FIGS. 26 and 27 show an electric field (upper side) of the ferroelectric layer and polarization (lower side) of the ferroelectric layer.

As can be seen from FIGS. 22 to 27, it can be seen that the ferroelectric field effect transistor (high-k single spacer) according to Comparative Example 1 and the ferroelectric field effect transistor (double spacer) according to the experimental example have a low electric field in the vicinity of the source/drain and the vicinity of the center of the channel due to the suppression effect. However, in the ferroelectric field effect transistor (low-k single spacer) according to Comparative Example 2, it can be seen that the electric field of the gate dielectric layer in the vicinity of the source/drain is high and the electric field in the vicinity of the center of the channel is also increased by a certain value. Accordingly, it can be seen that the ferroelectric field effect transistor (high-k single spacer) according to Comparative Example 1 and the ferroelectric field effect transistor (double spacer) according to the experimental example have an effective suppression effect.

In addition, it can be seen that the gate dielectric layer electric fields of the ferroelectric field effect transistor (high-k single spacer) according to Comparative Example 1 and the ferroelectric field effect transistor (double spacer) according to the experimental example are similar, but the electric field of the ferroelectric layer is higher in the field effect transistor (double spacer) according to the experimental example. This is due to the relocation effect, that the electric field of the and it can be seen ferroelectric layer is formed higher, so the that polarization is also formed high.

### Experimental Example 4: Confirmation of Optimal Thickness of Lower Spacer of Ferroelectric Field Effect Transistor

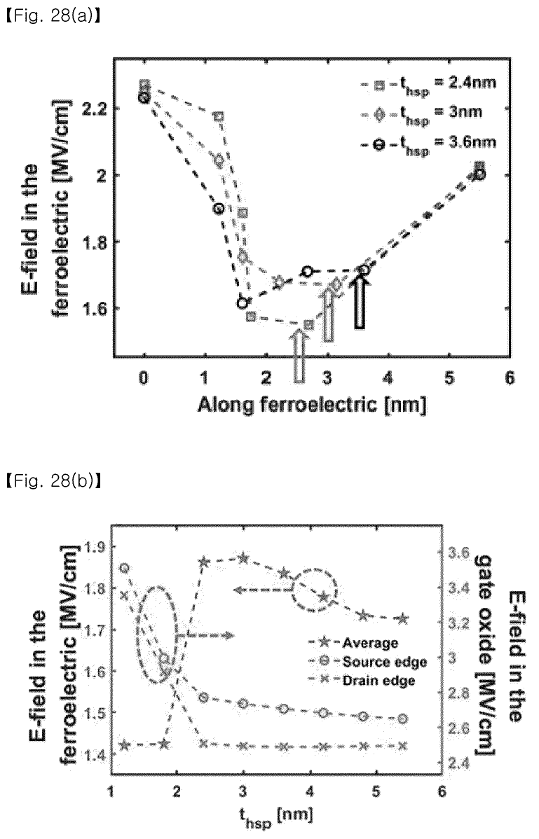

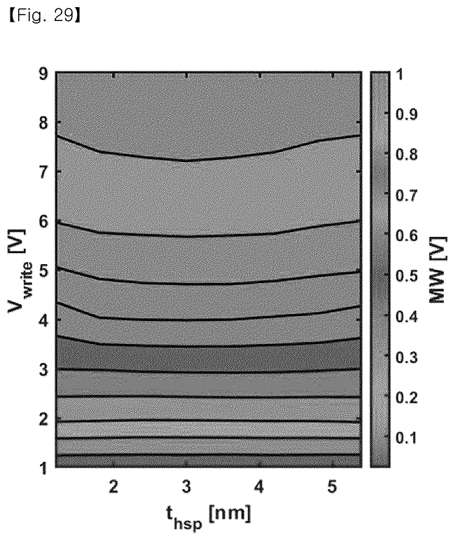

FIGS. 28 and 29 are views comparing characteristics according to a thickness of a lower spacer of the ferroelectric field effect transistor according to the experimental example of the present invention.

FIG. 28(a) shows changes in electric fields (E-field in the ferroelectric, MV/cm) according to a thickness of the lower spacer (tₕₛₚ=2.4 nm, 3 nm, and 3.6 nm) within a thickness range (Along ferroelectric, nm) of the ferroelectric layer.

As can be seen in FIG. 28(a), it can be seen that the electric field is rapidly decreased until the thickness of the ferroelectric layer is equal to the thickness of the lower spacer, and the substantially constant electric field is maintained, and then the electric field gradually increases from a range in which the thickness of the ferroelectric layer becomes thicker than the thickness of the lower spacer. That is, it can be seen that the electric field of the ferroelectric layer is improved as the relocation effect occurs at a position where a boundary surface between the lower spacer and the upper spacer is located.

FIG. 28(b) shows changes in the electric field in the ferroelectric layer (E-filed in the ferroelectric, MV/cm) and electric fields in the gate dielectric layer (E-filed in the gate oxide, MV/cm) according to a thickness of the lower spacer (tₕₛₚ, nm). The electric field change in the gate dielectric layer represents a value measured at a source edge and a value measured at a drain edge, and the electric field change in the ferroelectric layer represents an average value.

As can be seen in FIG. 28(b), it can be seen that the electric field in the gate dielectric layer is rapidly increased as the thickness of the lower spacer is about 2 nm or greater, and then is decreased again as the thickness of the lower spacer exceeds 3 nm. In addition, it can be seen that the electric field change in the gate dielectric layer continuously decreases until the thickness of the lower spacer is about 2.4 nm and then becomes saturated (substantially constant electric field is maintained).

FIG. 29 shows a relationship between a write voltage (V_{write}, V) and a thickness (tₕₛₚ, nm) of the lower spacer. Specific values between the write voltage (V_{write}, V) and the thickness (tₕₛₚ, nm) of the lower spacer are summarized in <Table 4> and <Table 5>.

TABLE 4

| | tₕₛₚ = 1.2 | tₕₛₚ = 1.8 | tₕₛₚ = 2.4 | tₕₛₚ = 3.0 |
|---|---|---|---|---|
| Classification | nm | nm | nm | nm |
| V_{write} = 1 V | 0.029524 | 0.028121 | 0.027394 | 0.028304 |
| V_{write} = 2 V | 0.323524 | 0.318116 | 0.312221 | 0.313915 |
| V_{write} = 3 V | 0.502151 | 0.505131 | 0.512569 | 0.515983 |
| V_{write} = 4 V | 0.649411 | 0.695688 | 0.701264 | 0.703189 |
| V_{write} = 5 V | 0.794197 | 0.82459 | 0.836832 | 0.841625 |
| V_{write} = 6 V | 0.905018 | 0.925618 | 0.927013 | 0.929314 |
| V_{write} = 7 V | 0.963076 | 0.98403 | 0.991746 | 0.991238 |
| V_{write} = 8 V | 1.014427 | 1.02492 | 1.029965 | 1.034247 |
| V_{write} = 9 V | 1.038599 | 1.047153 | 1.044365 | 1.046164 |

TABLE 5

| | tₕₛₚ = 3.6 | tₕₛₚ = 4.2 | tₕₛₚ = 4.8 | tₕₛₚ = 5.4 |
|---|---|---|---|---|
| Classification | nm | nm | nm | nm |
| V_{write} = 1 V | 0.02549 | 0.02871 | 0.025589 | 0.023459 |
| V_{write} = 2 V | 0.316829 | 0.318818 | 0.319879 | 0.326007 |
| V_{write} = 3 V | 0.517176 | 0.515179 | 0.50856 | 0.50125 |
| V_{write} = 4 V | 0.7008 | 0.69188 | 0.68364 | 0.65991 |
| V_{write} = 5 V | 0.8418 | 0.83272 | 0.81748 | 0.80675 |
| V_{write} = 6 V | 0.92642 | 0.92518 | 0.911745 | 0.9013 |
| V_{write} = 7 V | 0.988747 | 0.98255 | 0.97364 | 0.976434 |
| V_{write} = 8 V | 1.030703 | 1.028557 | 1.016731 | 1.008829 |
| V_{write} = 9 V | 1.04722 | 1.044336 | 1.038088 | 1.03558 |

As can be seen from FIG. 29, <Table 4>, and <Table 5>, it can be seen that when the thickness of the lower spacer is 3 nm, an increase rate of the memory window according to the increase in the write voltage is the highest.

As a result, it is found through Experimental Example 4 that optimization for the thickness of the lower spacer is required. Specifically, it can be seen that the optimal thickness of the lower spacer for improving characteristics of the ferroelectric layer field effect transistor is 3 nm, a lower limit value is 2.4 nm, and an upper limit value is 3.6 nm.

While the present invention has been described in connection with the embodiments, it is not to be limited thereto but will be defined by the appended claims. In addition, it is to be understood that those skilled in the art can substitute, change, or modify the embodiments in various forms without departing from the scope and spirit of the present invention.

What is claimed is:

1. A ferroelectric field effect transistor comprising:
a body layer including a source region, a drain region spaced apart from the source region, and an intermediate region disposed between the source region and the drain region;
a gate structure including a gate dielectric layer, a ferroelectric layer, and a gate electrode which are sequentially stacked on the intermediate region of the body layer; and
a double spacer disposed on a side wall of the gate structure,
wherein the double spacer includes a high-k lower spacer and a low-k upper spacer disposed on the lower spacer.

2. The ferroelectric field effect transistor of claim 1, wherein, when a voltage is applied to the gate electrode, a relatively high electric field is formed in the ferroelectric layer and a relatively low electric field is formed in the gate dielectric layer.

3. The ferroelectric field effect transistor of claim 1, wherein a boundary surface between the lower spacer and the upper spacer is located adjacent to the ferroelectric layer of the gate structure.

4. The ferroelectric field effect transistor of claim 1, wherein a side wall of the lower spacer makes contact with both a side wall of the gate dielectric layer and a side wall of the ferroelectric layer.

5. The ferroelectric field effect transistor of claim 1, wherein a side wall of the upper spacer makes contact with both a side wall of the ferroelectric layer and a side wall of the gate electrode.

6. The ferroelectric field effect transistor of claim 1, wherein a lower surface of the lower spacer makes contact with any one of the source region and the drain region.

7. The ferroelectric field effect transistor of claim 1, wherein the lower spacer includes hafnium oxide (HfO₂), and the upper spacer includes silicon oxide (SiO₂).

8. The ferroelectric field effect transistor of claim 1, wherein the gate dielectric layer includes silicon oxide (SiO₂).

9. The ferroelectric field effect transistor of claim 1, wherein the ferroelectric layer includes hafnium zirconium oxide (HZO).

10. The ferroelectric field effect transistor of claim 1, wherein the lower spacer has a thickness greater than 2.4 nm and less than 3.6 nm.

11. A method of manufacturing a ferroelectric field effect transistor, the method comprising:
preparing a substrate;
forming a body layer on the substrate;
forming a gate structure, in which a gate dielectric layer, a ferroelectric layer, and a gate electrode are sequentially stacked, on an intermediate region of the body layer;
forming a source region and a drain region by injecting a dopant into a first region of the body layer adjacent to one side of the gate structure and a second region of the body layer adjacent to the other side of the gate structure;
forming a high-k lower spacer on the source region and the drain region; and
forming a low-k upper spacer on the lower spacer.

12. The method of claim 11, wherein the lower spacer is formed such that a level of an upper surface of the lower spacer is located between levels of an upper surface and a lower surface of the ferroelectric layer.

13. The method of claim 11, wherein the forming of the gate structure includes:
forming the gate dielectric layer on the body layer;
forming the ferroelectric layer on the gate dielectric layer;
forming the gate electrode on the ferroelectric layer; and
etching the gate dielectric layer, the ferroelectric layer, and the gate electrode such that the first region and the second region of the body layer are exposed to an outside.

14. The method of claim 11, wherein the forming of the lower spacer includes:
forming a high-k material layer on the body layer such that the source region, the drain region, and the gate structure are conformally covered with the high-k material layer; and
etching the high-k material layer such that an upper portion and a part of a side wall of the gate structure are exposed.
